(19) United States
(12) Patent Application Publication
(10) Pub. No.: US 2026/0047182 A1
(43) Pub. Date: Feb. 12, 2026

(54) DEVICE INCLUDING INTEGRATED TRENCH MOSFET AND SCHOTTKY BARRIER DIODE

(71) Applicant: Microchip Technology Incorporated, Chandler, AZ (US)

(72) Inventors: Shesh Mani Pandey, Gilbert, AZ (US); Bruce Odekirk, Portland, OR (US); George Dorman, Chandler, AZ (US)

(73) Assignee: Microchip Technology Incorporated, Chandler, AZ (US)

(21) Appl. No.: 19/207,217

(22) Filed: May 13, 2025

Related U.S. Application Data
(60) Provisional application No. 63/682,257, filed on Aug. 12, 2024.

(51) Int. Cl. H10D 84/00; H10D 8/01; H10D 8/60; H10D 30/01; H10D 30/66; H10D 62/10; H10D 64/64; H10D 64/66

(52) U.S. Cl. CPC H10D 84/146; H10D 8/60; H10D 30/668; H10D 62/124; H10D 64/64; H10D 64/661; H10D 8/051; H10D 30/0297

(57) ABSTRACT

A device including a trench metal oxide field-effect transistor and a Schottky barrier diode physically and functionally integrated into a single, continuous structure, and a method of making such a device. A first transistor includes a first trench, a first channel on one side of the first trench, and a first doped region on the opposite side of the first trench. An optional second transistor is a mirror-image of the first and includes a second trench, a second channel on one side of the second trench, and a second doped region on the opposite side of the second trench. The Schottky barrier diode is shared by the first and second trench transistors and includes a Schottky material located adjacent to and overlapping the first and second doped regions. An electrical terminal may connect first and second sources and the Schottky barrier diode.

### RELATED APPLICATION

The present U.S. non-provisional patent application is related to and claims priority benefit of an earlier-filed U.S. provisional patent application titled “Device Including Trench MOSFET and Schottky Barrier Diode Integrated Into Single, Continuous Structure,” Ser. No. 63/682,257, filed Aug. 12, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a device including an integrated trench MOSFET and a Schottky barrier diode, and a method of making a device including an integrated trench MOSFET and a Schottky barrier diode.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a device including a trench MOSFET and a Schottky barrier diode (SBD) physically and functionally integrated into a single, continuous structure, and a method of making a device including a trench MOSFET and an SBD physically and functionally integrated into a single, continuous structure. Broadly, the SBD is located adjacent to a doped (P+ according to certain examples of the present invention) region and on an opposite side of a trench from a channel. Examples advantageously provide the benefits of improved reverse conduction and lower cost, and the doped region provides increased shielding for the SBD.

In an example, a semiconductor device may include a volume of semiconductor material, a first trench field-effect transistor, and a Schottky barrier diode. The volume of semiconductor material may include a first end and a second end. The first trench field-effect transistor may include a first source located at the first end of the volume of semiconductor material, a first drain, a first channel provided by a region of the volume of semiconductor material between the first source and the first drain, a first trench extending into the volume of semiconductor material from the first end (the first trench may present spaced apart first trench sides extending from the first end, with one of the first trench sides being adjacent to the first channel), a first dielectric material located within the first trench along at least the first trench side adjacent the first channel, a first gate located within the first trench, and a first doped region in the volume of semiconductor material. At least a portion of the first doped region may be located on the first trench side opposite the first channel. The Schottky barrier diode may be located at the first end of the volume of semiconductor material adjacent to the same first trench side as the first doped region. The Schottky barrier diode may include a Schottky material on a surface of the first end of the volume of semiconductor material. The Schottky material may overlap the first doped region.

The preceding example may further include any one or more of the following features. The first doped region may extend from the first end of the volume of semiconductor material and underlie at least part of the first trench. The first trench may present a first trench bottom, the first trench sides may extend between first trench bottom and the first end of the volume of semiconductor material, and the first doped region may abut and extend along at least part of the first trench bottom. The first gate oxide may line the first trench bottom and the first trench sides. The first source and the Schottky barrier diode may be electrically connected. The first drain may be located at the second end of the volume of semiconductor material. The first doped region may include a P+ material, the volume semiconductor material may include an N-type epitaxial material, the first source may include an implanted N+ material, the first drain may include an N+ substrate material, the first dielectric material may include a silicon dioxide, and the first gate may include a doped polysilicon material. The Schottky material may be selected from the group consisting of: aluminum, titanium, molybdenum, platinum, chromium, tungsten, and combinations thereof. The first trench field-effect transistor may include a first well abutting the first source between the first source and the first drain. The first trench field-effect transistor may also include a first body located adjacent to the source. The device may include a first electrical terminal electrically connecting the first source, the first body, and the Schottky barrier diode; a second electrical terminal on the first drain; and a third electrical terminal on the first gate. The device may also include a second trench field-effect transistor located on an opposite side of the Schottky barrier diode from the first trench field-effect transistor, wherein the Schottky barrier diode is shared by the first and second trench field-effect transistors. The second trench field-effect transistor may include a second source located at the first end of the volume of semiconductor material, a second drain, a second channel provided by a region of the volume of semiconductor material between the second source and the second drain, a second trench extending into the volume of semiconductor material from the first end (the second trench may present spaced apart second trench sides extending from the first end, with one of the second trench sides being adjacent to the second channel), a second dielectric material located within the second trench along at least the second trench side adjacent the second channel, a second gate located within the second trench, and a second doped region in the volume of semiconductor material. At least a portion of the second doped region may be located on the second trench side opposite the second channel. The Schottky barrier diode may be located adjacent to the same second trench side as the second doped region. The first and second sources and the Schottky barrier diode may be electrically connected. The first and second doped regions may extend from the first end of the volume of semiconductor material. The first and second first doped regions may be adjacent one another but spaced apart by a portion of the volume of semiconductor material. The Schottky material may overlap the second doped region and the portion of the volume of semiconductor material. The first and second trench field-effect transistors may be mirror images of one another. The first and second drains may be integrally formed by a substrate located at the second end of the volume of semiconductor material.

This summary is not intended to identify essential features of the examples, and is not intended to be used to limit the scope of the claims. These and other aspects of the present invention are described below in greater detail.

### DRAWINGS

Examples are described in detail below with reference to the attached drawing figures, wherein:

FIG. 1 is a cross-sectional elevation view of an example of a device including an integrated trench MOSFET and SBD, wherein the SBD is located adjacent to a P+ implant and on an opposite side of the trench from a channel;

FIG. 2 is a flowchart of operations in an example of a method of manufacturing a device including an integrated trench MOSFET and SBD, wherein the SBD is located adjacent to a P+ implant and on an opposite side of the trench from a channel;

FIG. 3A is a cross-sectional elevation view of the result of an operation in the method of FIG. 2, wherein an N-type epitaxial semiconductor material is shown on an N+ drain, and a P-well of a P-type material, an N+ source, a P+ body, and a volume of P+ material are implanted in the N-type epitaxial semiconductor material;

FIG. 3B is a cross-sectional elevation view of the result of an operation in the method of FIG. 2, wherein a trench is etched, a gate oxide is grown, and a polysilicon gate is deposited; and

FIG. 3C is a cross-sectional elevation view of the result of an operation in the method of FIG. 2, wherein a Schottky material is provided and electrical terminals are added.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples concern a device including a trench MOSFET and an SBD physically and functionally integrated into a single, continuous structure, and a method of making a device including a trench MOSFET and an SBD physically and functionally integrated into a single, continuous structure. Broadly, the SBD may be located adjacent to a doped region (such as a P+implant) on an opposite side of a trench from a channel. Examples advantageously provide the benefits of improved reverse conduction and lower cost, and the doped region provides increased shielding for the SBD. More specifically, the improved reverse conduction (i.e., the third quadrant performance) of a silicon carbide (SIC) MOSFET is desirable for next-generation compact power electronics. Integration of the SBD with the SiC MOSFET provides an efficient mechanism for avoiding bipolar degradation when the parasitic P-N body diode is opened. If the forward voltage of the body diode of the MOSFET is three-and-on-half (3.5) volts (V), and the forward voltage of the SBD is one-and-one-half (1.5) V, then the forward voltage drop is reduced by two (2) V, resulting in lower forward voltage losses. Further, integrating the SBD rather than connecting a discrete SBD provides the advantages of using less space, lowering cost, and requiring fewer dies in the manufacturing process.

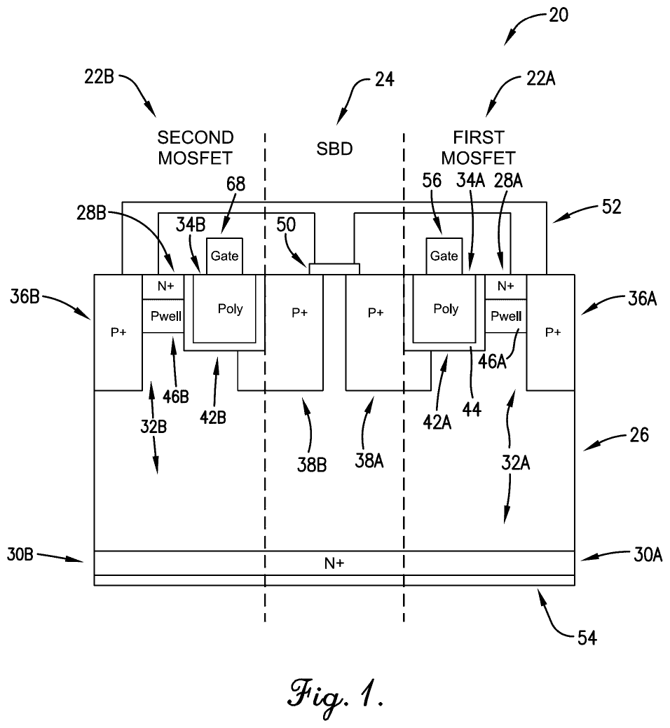

Referring to FIG. 1, an example of a device 20 including a (first) trench MOSFET 22A and an SBD 24 integrated into a single, continuous structure is shown. The device 20 may include a volume of semiconductor material 26 including a first end and second end. The semiconductor material 26 may be an N-type epitaxial semiconductor material. The trench MOSFET 22A may include a source 28A, a drain 30A, a channel 32A, a gate 34A, a body 36A, and a doped region 38A. The source 28A may be located at the first end of the semiconductor material 26 and provide an entrance for the majority charge carriers into the channel 32A (which are, in this case, electrons). The source 28A may be constructed from or include N+ material implanted (with, e.g., an ion implanter) into the semiconductor material 26. The drain 30A may be located at the second end of the semiconductor material 26, opposite and spaced apart from the source 28A, and provide an exit for the majority charge carriers. However, according to some alternative aspects of the example device, the source may instead be located at the first end of the volume of semiconductor material. The drain 30A may be constructed from or include an N+material substrate on which the semiconductor material 26 may be grown or otherwise provided. The channel 32A may be a region of the semiconductor material 26 between the source 28A and the drain 30A through which the majority charge carriers move, i.e., through which electrical current flows. The gate 34A may cooperate with the body 36A to facilitate control over the flow of charge carriers through the channel 32A. The gate 34A may be constructed from or include a doped polysilicon material. The gate 34A may be located in a trench 42A etched or otherwise created in the semiconductor material 26. The trench 42A may be lined with a dielectric material 44, or gate oxide, such as SiO2. The trench preferably presents a trench bottom and trench sides extending between the trench bottom and the first end of the volume of semiconductor material. The dielectric material 44 may extend along at least the trench side adjacent the source 28A (the channel), but the illustrated example depicts the dielectric material lining the trench bottom and both trench sides. In certain additional aspects of the example device, the dielectric material may substantially fill the trench 42A.

The body 36A may cooperate with the gate 34A to control the electrical current flow between the source 28A and the drain 30A. The body 36A may be constructed from or include a P+ material implanted into the semiconductor material 26. The doped region 38A may be located on an opposite side of the trench 42A from the channel 32A, and the doped region 38A may abut the dielectric material lining the adjacent side of the trench 42A. In certain aspects of the example device, the doped region 38A also abuts and extends along at least part of the trench bottom. The doped region 38A may be formed of a P+ implant. Additionally, a well 46A, which may be formed of a P-type material, may be implanted in the semiconductor material 26 below the source 28A.

The SBD 24 may be located at the first end of the volume of semiconductor material 26 and on the opposite side of the trench 42A from the channel 32A and adjacent to the doped region 38A, thereby physically and functionally integrating the MOSFET 22A and SBD 24 into the single, continuous structure of the device 20. The SBD 24 may include a Schottky material 50. The Schottky material 50 may be deposited or otherwise provided atop or on a surface of the first end of the volume of semiconductor material 26, and may overlap the doped region 38A. The Schottky material 50 may be or include aluminum, titanium, molybdenum, platinum, chromium, tungsten, or combinations thereof.

A first electrical terminal 52 may be provided on and electrically connect the source 28A, the body 36A, and the Schottky material 50; a second electrical terminal 54 may be provided on the drain 30A; and a third electrical terminal 56 may be provided on the gate 34A, wherein the various electrical terminals facilitate applying various voltages, as described below.

As also seen in FIG. 1, a second trench MOSFET 22B, which structurally may be a mirror-image of (i.e., flipped along a vertical line or axis running through the SBD 24) but otherwise substantially similar or identical to the first trench MOSFET 22A, may be provided on an opposite side of the SBD 24. However, it is within the ambit of certain aspects of the example device for the second trench MOSFET to be alternatively constructed or, in some cases, for an entirely different FET to be provided on the opposite side of the SBD 24.

The second trench MOSFET 60 may include a second source 28B, a second drain 30B, a second channel 32B, a second gate 34B, a second body 36B, a second doped region 38B, a second trench 44B, and a second well 46B. The SBD 24 may be located between the first and second trench MOSFETs 22A, 22B and above the first and second doped regions 38A, 38B. The SBD 24 may overlap (be in contact with) at least one, but preferably both, of the first and second doped regions 38A, 38B. It is particularly noted that the doped regions 38A, 38B may be split so that a portion of the epitaxially grown volume of semiconductor material 26 (a portion of the drift region) is located between the doped regions 38A, 38B, with the SBD overlapping (being in contact with) such portion of the volume of semiconductor material 26. The first electrical terminal 52 may electrically connect the first source 28A, the first body 36A, the second source 28B, the second body 36B, and the SBD 24. Further, a fourth electrical terminal 68 may be provided on the second gate 34B of the second MOSFET 22B. It is further noted that the first and second drains 30A, 30B may be integrally formed by the substrate located at the second end of the volume of semiconductor material 26.

In operation, when a voltage, Vgs, is applied between the sources 28A, 28B and the gates 34A, 34B, the electric field generated penetrates through the respective gate oxide layer 44 lining the trenches 42A, 42B and creates inversion layers or channels at the semiconductor-dielectric interfaces. The inversion layers provides the channels 32A, 32B through which electrical current can flow when a voltage, Vds, is applied between the sources 28A, 28B and the drains 30A, 30B. More specifically, Vgs controls the width of the depletion region at the P-N junctions where the charge carriers of the P- and N-type materials diffuse into each other, which “depletes” the available concentrations of majority charge carriers in each material, and thereby controls the current, Id, from the drains 30A, 30B to the sources 28A, 28B. As discussed, the integrated SBD 24 avoids bipolar degradation when the parasitic P-N body diode is opened.

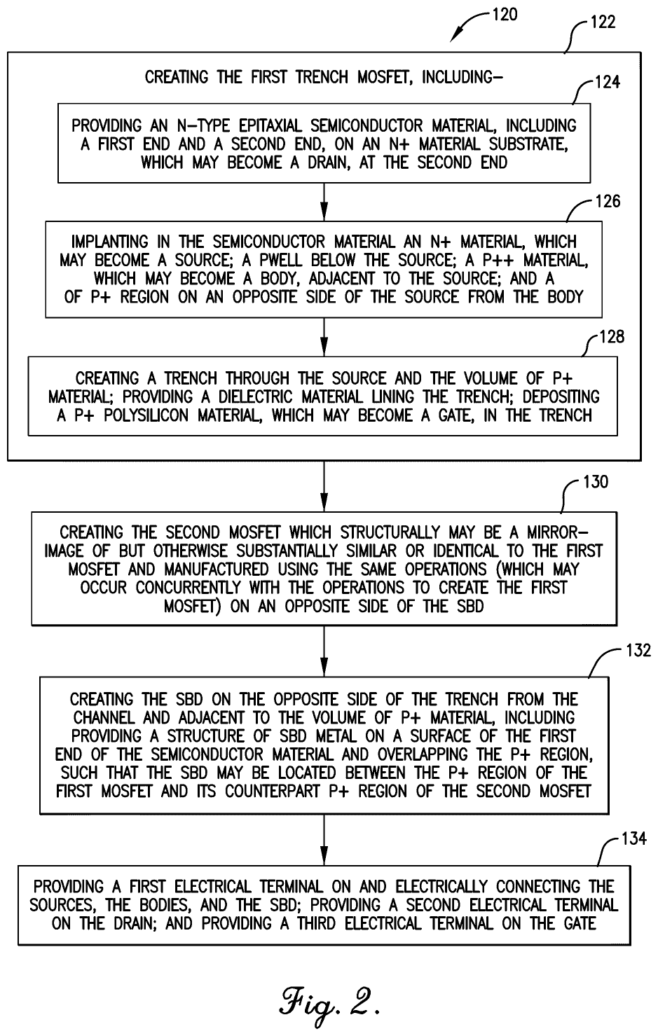

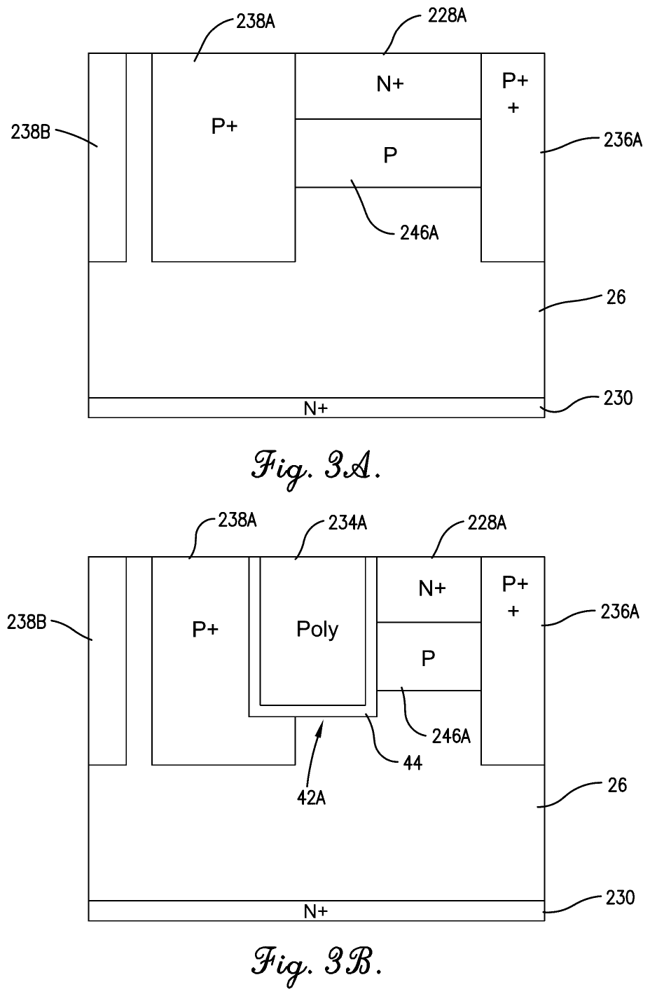

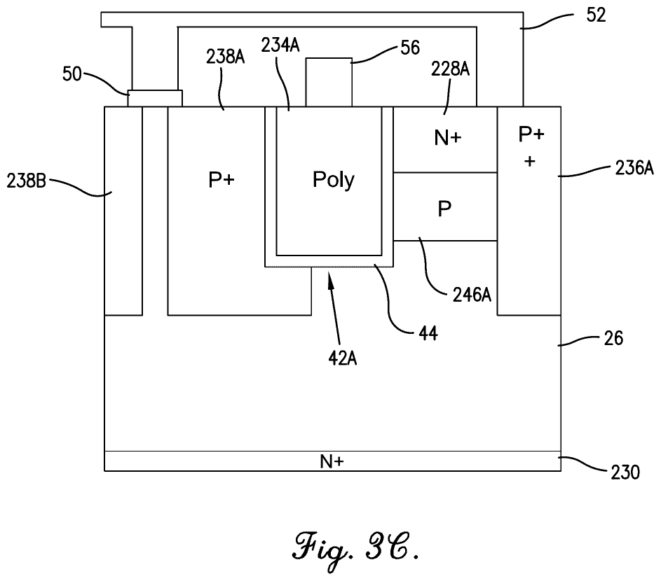

Referring to FIG. 2, an example of method 120 of manufacturing the device 20 described above, including a (first) trench MOSFET 22A and an SBD 24 integrated into a single, continuous structure may include the operations set forth below. Referring additionally to FIGS. 3A-C, example results of various operations are shown. The method 120 may begin by epitaxially growing a volume of semiconductor material 26, including a first end and a second end, on a substrate material 230. The substrate material 20 may become the drains 30A, 30B at the second end of the volume of semiconductor material, as shown in 122 and seen in FIG. 3A. The semiconductor material 26 may be N-type semiconductor material, and the substrate material may be N+ substrate material.

The trench MOSFET 22A may be created, as shown in 124. An N+ material 228A, which may become a source 28A, may be implanted (using, e.g., an ion implanter) in the first end of the semiconductor material 26; a P-type material 246A which may become a P-well 46A may be implanted in the semiconductor material 26 below the source 28A; a P+ material 236A which may become a body 36A, may be implanted in the semiconductor material 26 adjacent to the source 28A; and a P+ material 238A which may form a P+ region 38A may be implanted in the semiconductor material 26 on an opposite side of the N+ source material 228A from the body 36A, as shown in 126 and also seen in FIG. 3A.

A trench 42A may be etched or otherwise created through the N+ source material 228 and the P+ region material region 238A; a dielectric material (e.g., SiO2) 44 may be deposited or otherwise provided lining the trench 42A; and a doped polysilicon material 234A, which may become a gate 34A, may be deposited in the trench 42A, as shown in 128 and seen in FIG. 3B.

A second trench MOSFET 22B may be created. As noted, the second trench MOSFET 22B may be a structural mirror-image of (i.e., flipped along a vertical line or axis running through the SBD 24) but otherwise substantially similar or identical to the MOSFET 22A, and may be manufactured using the same operations (which may occur concurrently with the operations to create the first MOSFET 22A) on an opposite side of the SBD 24, as shown in 130 and seen in FIG. 1.

The SBD 24 may be created on the opposite side of the trench 42A from the channel 32A and adjacent to the P+ region material 238A, thereby physically and functionally integrating the MOSFET 22A and SBD 24 into the single, continuous structure of the device 20. Creating the SBD 24 may include depositing or otherwise providing a structure of Schottky material 50 atop or on a surface of the first end of the semiconductor material 26 and overlapping the P+ region material 238A, as shown in 132 and seen in FIG. 3C. The SBD 50 metal may be or include aluminum, titanium, molybdenum, platinum, chromium, tungsten, or combinations thereof. If the second MOSFET 22B is created, then the single, shared SBD 24 may be located between the P+region material 238A of the first MOSFET 22A and its counterpart P+ region material 238B of the second MOSFET 22B (as seen in FIG. 1).

A first electrical terminal 52 may be provided on and electrically connecting the N+ source material 228A, the P+ body material 236A, and the Schottky material 50; a second electrical terminal 54 may be provided on the N+ drain substrate material 230; and a third electrical terminal 56 may be provided on the doped polysilicon gate material 234A, as shown in 134 and seen in FIG. 3C, wherein the various electrical terminals facilitate applying various voltages, as described above. If the second MOSFET 22B is included, the first electrical terminal may electrically connect the first N+ source material 228A and the first P+ body material 236A of the first MOSFET 22A, a second N+ source material and second P+ body material of the second MOSFET 22B, and the SBD 24. Further, a fourth electrical terminal may be provided on the second doped polysilicon gate material of the second MOSFET 22B. In some aspects, the third and fourth electrical terminals may be shorted. Additional processing may occur as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

It will be appreciated that the sides of the illustrated volume of semiconductor material are defined herein merely as an example, and may in various examples represent only a portion of semiconductor material relative to the illustrated device. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated MOSFETs 22A, 22B) or may be entirely different devices providing different operations or functions than the illustrated MOSFETs 22A, 22B. In other words, in practice, the illustrated MOSFETs 22A, 22B may be just a subset of numerous devices spaced laterally and transversely within a single, integrally formed array, such as a wafer (not shown).

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A semiconductor device comprising:
a volume of semiconductor material including a first end and a second end;
a first trench field-effect transistor including—
a first source located at the first end of the volume of semiconductor material,
a first drain,
a first channel provided by a region of the volume of semiconductor material between the first source and the first drain,
a first trench extending into the volume of semiconductor material from the first end,
the first trench presenting spaced apart first trench sides extending from the first end, with one of the first trench sides being adjacent to the first channel,
a first dielectric material located within the first trench along at least the first trench side adjacent the first channel,
a first gate located within the first trench, and
a first doped region in the volume of semiconductor material, with at least portion of the first doped region being located on the first trench side opposite the first channel; and
a Schottky barrier diode located at the first end of the volume of semiconductor material adjacent to the same first trench side as the first doped region,
the Schottky barrier diode including a Schottky material on a surface of the first end of the volume of semiconductor material,
the Schottky material overlapping the first doped region.

2. The device of claim 1,
the first doped region extending from the first end of the volume of semiconductor material and underlying at least part of the first trench.

3. The device of claim 2,
the first trench presenting a first trench bottom,
the first trench sides extending between the first trench bottom and the first end of the volume of semiconductor material,
the first doped region abutting and extending along at least part of the first trench bottom.

4. The device of claim 3,
the first gate oxide lining the first trench bottom and the first trench sides.

5. The device of claim 4,
the first source and the Schottky barrier diode being electrically connected.

6. The device of claim 5,
the first drain being located at the second end of the volume of semiconductor material.

7. The device of claim 6,
the first doped region including a P+ material,
the volume semiconductor material including an N-type epitaxial material,
the first source including an implanted N+ material,
the first drain including an N+ substrate material,
the first dielectric material including a silicon dioxide,
the first gate including a doped polysilicon material.

8. The device of claim 7,
the Schottky material being selected from the group consisting of: aluminum, titanium, molybdenum, platinum, chromium, tungsten, and combinations thereof.

9. The device of claim 8,
the first trench field-effect transistor including a first well abutting the first source between the first source and the first drain; and
the first trench field-effect transistor including a first body located adjacent to the source.

10. The device of claim 9, comprising:
a first electrical terminal electrically connecting the first source, the first body, and the Schottky barrier diode;
a second electrical terminal on the first drain; and
a third electrical terminal on the first gate.

11. The device of claim 1,
the first source and the Schottky barrier diode being electrically connected.

12. The device of claim 1,
the first drain being located at the second end of the volume of semiconductor material.

13. The device of claim 1,
the first doped region including a P+ material,
volume of semiconductor material including an N-type epitaxial material,
the first source including an implanted N+ material,
the first drain includeing an N+ substrate material,
the first dielectric material including a silicon dioxide,
the first gate including a doped polysilicon material.

14. The device of claim 1,
the Schottky material being selected from the group consisting of: aluminum, titanium, molybdenum, platinum, chromium, tungsten, and combinations thereof.

15. The device of claim 1,
the first trench field-effect transistor including a first well abutting the first source between the first source and the first drain,
the first trench field-effect transistor including a first body located adjacent to the first source;
a first electrical terminal electrically connecting the first source, the first body, and the Schottky barrier diode;
a second electrical terminal on the first drain; and
a third electrical terminal on the first gate.

16. The device of claim 1, comprising:
a second trench field-effect transistor located on an opposite side of the Schottky barrier diode from the first trench field-effect transistor, wherein the Schottky barrier diode is shared by the first and second trench field-effect transistors.

17. The device of claim 16,
the second trench field-effect transistor including—
a second source located at the first end of the volume of semiconductor material,
a second drain,
a second channel provided by a region of the volume of semiconductor material between the second source and the second drain,
a second trench extending into the volume of semiconductor material from the first end,
the second trench presenting spaced apart second trench sides extending from the first end, with one of the second trench sides being adjacent to the second channel,
a second dielectric material located within the second trench along at least the second trench side adjacent the second channel,
a second gate located within the second trench, and
a second doped region in the volume of semiconductor material, with at least portion of the second doped region being located on the second trench side opposite the second channel, the Schottky barrier diode being located adjacent to the same second trench side as the second doped region.

18. The device of claim 17,
the first and second sources and the Schottky barrier diode being electrically connected.

19. The device of claim 18,
the first and second doped regions extending from the first end of the volume of semiconductor material,
the first and second first doped regions being adjacent one another but spaced apart by a drift portion of the volume of semiconductor material,
the Schottky material overlapping the second doped region and the portion of the volume of semiconductor material.

20. The device of claim 17,
the first and second trench field-effect transistors being mirror images of one another,
the first and second drains being integrally formed by a substrate located at the second end of the volume of semiconductor material.
